(19) United States
(12) Patent Application Publication
(10) Pub. No.: US 2026/0251736 A1
(43) Pub. Date: Aug. 27, 2026

(54) THERMAL ISOLATION FOR MODULAR QUANTUM SENSOR

(71) Applicant: Mesa Quantum Systems, Inc., Boulder, CO (US)

(72) Inventors: William Raasch, Longmont, CO (US); Antonio Jose Yervez Gonzalez, Longmont, CO (US); John Gariano, Dancono, CO (US); Sristy Agrawal, Longmont, CO (US); Olawale Lawal, Sachse, TX (US)

(21) Appl. No.: 19/549,762

(22) Filed: Feb. 25, 2026

Related U.S. Application Data
(60) Provisional application No. 63/763,413, filed on Feb. 26, 2025.

(51) Int. Cl. G01R 33/26

(52) U.S. Cl. CPC G01R 33/26

(57) ABSTRACT

A quantum sensor device may include a first functional module that includes a first component and a first temperature control system configured to maintain the first component at a first operating temperature, a second functional module that includes a second component and a second temperature control system configured to maintain the second component at a second operating temperature different from the first operating temperature and a thermal isolation structure disposed between the first functional module and the second functional module, including one of a vacuum gap, a radiation shield, or a reduced conduction support structure. The thermal isolation structure includes one or more of a vacuum gap, a radiation shield, or a reduced conduction support structure and limits heat transfer between the first and second functional modules such that adjustment of the first operating temperature causes a change in the second operating temperature of less than a predetermined threshold.

### PRIORITY

This application claims the benefit of U.S. Provisional Patent Application No. 63/763,413, filed February 26, 2025, entitled MODULAR SYSTEM FOR MANUFACTURING QUANTUM DEVICES and naming William Raasch as the inventor, the disclosure of which is incorporated herein in its entirety by reference.

### STATEMENT REGARDING FEDERALLY SPONSORED RESEARCH OR DEVELOPMENT

This invention was made with Government support under Contract No. FA254124CB011 awarded by the United States Space Force. The Government has certain rights in the invention pursuant to 35 USC §200 et seq. and applicable implementing regulations.

### FIELD

Illustrative embodiments of the invention generally relate to quantum sensing devices and methods for manufacturing quantum sensing devices. More particularly, various embodiments of the invention relate to modular architectures with independent temperature control for quantum sensors including atomic clocks, magnetometers, and gyroscopes.

### BACKGROUND

Quantum sensors such as chip-scale atomic clocks (CSACs), atomic magnetometers, and quantum gyroscopes typically require multiple functional components operating along an optical interaction axis, including a light source, optical conditioning elements, an atomic vapor cell containing an alkali metal vapor, and a photodetector. These devices can be fabricated using different approaches, including MEMS (Micro-Electro-Mechanical Systems) techniques for semiconductor-based implementations and glass fabrication methods for glass-type cells. Each component has different optimal operating temperatures, and traditional designs place all components in close physical proximity within a monolithic assembly, creating challenges for independent temperature control, component testing, and manufacturing yield.

### SUMMARY OF VARIOUS EMBODIMENTS

Illustrative embodiments enable the use of modular pre-tested and temperature-adjusted assemblies directly into vapor cell manufacturing processes, dramatically lowering production time and costs and improving thermal compatibility of quantum sensors, including quantum magnetometers.

In accordance with one embodiment of the invention, a quantum sensor device may include a first functional module that includes a first component and a first temperature control system configured to maintain the first component at a first operating temperature, a second functional module that includes a second component and a second temperature control system configured to maintain the second component at a second operating temperature different from the first operating temperature and a thermal isolation structure disposed between the first functional module and the second functional module, including one of a vacuum gap, a radiation shield, or a reduced conduction support structure. The thermal isolation structure includes one or more of a vacuum gap, a radiation shield, or a reduced conduction support structure and limits heat transfer between the first and second functional modules such that adjustment of the first operating temperature causes a change in the second operating temperature of less than a predetermined threshold.

In accordance with other embodiments, the first and second functional modules may include one or more of a light generation module, an interaction module that includes an atomic vapor cell, and a light detection module.

In accordance with other embodiments, the light generation module is configured such that an output wavelength is tunable through temperature adjustment to match an atomic transition frequency of the atomic vapor cell.

In accordance with other embodiments, the atomic vapor cell may include a sealed atomic vapor chamber and an integrated heating element configured to maintain the vapor chamber at a temperature different from that of the light generation module.

In accordance with other embodiments, each functional module may include one or more thermal management components configured to regulate an operating temperature of that module independently of the other modules.

In accordance with other embodiments, the thermal isolation structure is selected from a vacuum gap, a radiation shield, and a reduced-conduction support structure.

In accordance with other embodiments, the thermal isolation structure is configured to maintain the functional modules in one or more of a reduced-pressure environment or inert gas environment to reduce convective thermal transfer between functional modules.

In accordance with other embodiments, the radiation shield may include a thermally reflective surface positioned to reduce radiative thermal transfer between adjacent functional modules operating at different temperatures.

In accordance with other embodiments, the first functional module is tested independently of the second functional module prior to assembling into the quantum sensor device.

In accordance with other embodiments, testing may include evaluating performance while operating each functional module at a target operating temperature that corresponds to the functional module being tested.

In accordance with other embodiments, a quantum sensing system may include a modular quantum device assembly that includes a plurality of functional modules arranged along an interaction axis. The functional modules may include a light generation module, an interaction module that includes an atomic vapor cell, and a light detection module. The modules are mechanically aligned by predefined alignment features that establish optical coupling along the interaction axis upon assembly. Each functional module may include independent temperature control and is configured to maintain an operating temperature independent of operating temperatures of other functional modules.

In accordance with other embodiments, a method of operating a quantum sensor device may include maintaining by a first temperature control system, a first component of a first functional module at a first operating temperature, maintaining by a second temperature control system, a second component of a second functional module at a second operating temperature different from the first operating temperature, thermally isolating the first functional module from the second functional module such that adjustment of the first operating temperature by the first temperature control system does not cause a change in the second operating temperature beyond a predetermined threshold, and adjusting the first operating temperature, the second operating temperature, or both, to achieve a specified operational parameter of the quantum sensor device.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a block diagram of a modular quantum sensor in accordance with embodiments of the invention.

FIG. 2 schematically shows a side view of a modular quantum sensor in accordance with embodiments of the invention.

FIG. 3 schematically shows a side view of a packaged modular quantum sensor in accordance with embodiments of the invention.

FIG. 4 schematically shows a top view of a modular quantum sensor in accordance with embodiments of the invention.

FIG. 5 schematically shows an isometric view of a modular quantum sensor in accordance with embodiments of the invention.

FIG. 6 schematically shows an exploded view of a modular quantum sensor in accordance with embodiments of the invention.

FIG. 7 schematically shows an isometric view of a VCSEL blade in accordance with embodiments of the invention.

FIG. 8 schematically shows an exploded isometric view of a vapor cell/magnetics blade in accordance with embodiments of the invention.

FIG. 9 schematically shows an isometric view of a photodetector blade in accordance with embodiments of the invention.

FIG. 10 shows a flowchart of a thermal management process for a modular quantum vapor cell in accordance with embodiments of the invention.

### DESCRIPTION OF ILLUSTRATIVE EMBODIMENTS

Vapor cells are known in the art and have been used for various applications including atomic clocks, quantum sensors, and magnetometers. These devices typically consist of a chamber with transparent windows and contain an alkali metal vapor. Vapor cells can be fabricated using different approaches, including MEMS (Micro-Electro-Mechanical Systems) techniques for semiconductor-based cells and glass fabrication methods for glass-type cells.

Quantum sensors such as chip-scale atomic clocks (CSACs), atomic magnetometers, and quantum gyroscopes require multiple functional components operating along an optical interaction axis. These components typically include a light source such as a vertical-cavity surface-emitting laser (or VCSEL), optical conditioning elements, an atomic vapor cell, and a photodetector. Each component has different optimal operating temperatures for peak performance.

Traditional quantum sensor designs attempt to minimize overall device size by placing all components in close physical proximity within a monolithic assembly. However, this approach creates several manufacturing challenges. First, components operating at different optimal temperatures are thermally coupled when placed in close proximity, making it difficult to maintain precise independent temperature control. For example, a VCSEL may operate optimally at 70-85°C to achieve a target wavelength, while an atomic vapor cell requires operation at 85-95°C to maintain proper vapor density. In a monolithic assembly, heating the vapor cell to its operating temperature unavoidably raises the temperature of the adjacent VCSEL, causing wavelength drift and requiring component binning or complex temperature compensation.

Second, traditional monolithic assemblies prevent independent testing of components before final assembly. Components can only be verified after the complete device is assembled, at which point a single defective component requires scrapping or reworking the entire assembly. This late-stage failure detection significantly reduces manufacturing yield, particularly as quantum sensors incorporate increasingly complex integrated optical and electronic components.

Third, the tight thermal coupling in monolithic assemblies requires component matching through pre-selection or "binning" - sorting components by their characteristics and pairing only those components whose operating parameters are compatible at a single shared operating temperature. For example, VCSELs must be wavelength-binned to find devices that emit at the target wavelength (e.g., 795 nm for rubidium) at the constrained temperature dictated by the vapor cell's optimal operating point. This binning requirement increases component inventory costs and limits manufacturing flexibility.

Fourth, once assembled, monolithic quantum sensors offer limited ability to adjust or optimize performance. If the VCSEL wavelength drifts slightly from the atomic transition frequency, or if the vapor cell operates away from its optimal temperature, there is insufficient thermal isolation to independently tune one component without affecting the others.

These manufacturing challenges have historically limited quantum sensor production yields in commercial CSAC manufacturing, making these devices expensive and restricting their use to specialized applications despite growing market demand for precision timing and sensing.

What is needed is a quantum sensor architecture that enables independent temperature control of functional components, allows independent testing before assembly, eliminates component binning requirements through post-selection tuning, and provides sufficient thermal isolation to maintain optimal operating conditions for each component throughout the device lifetime.

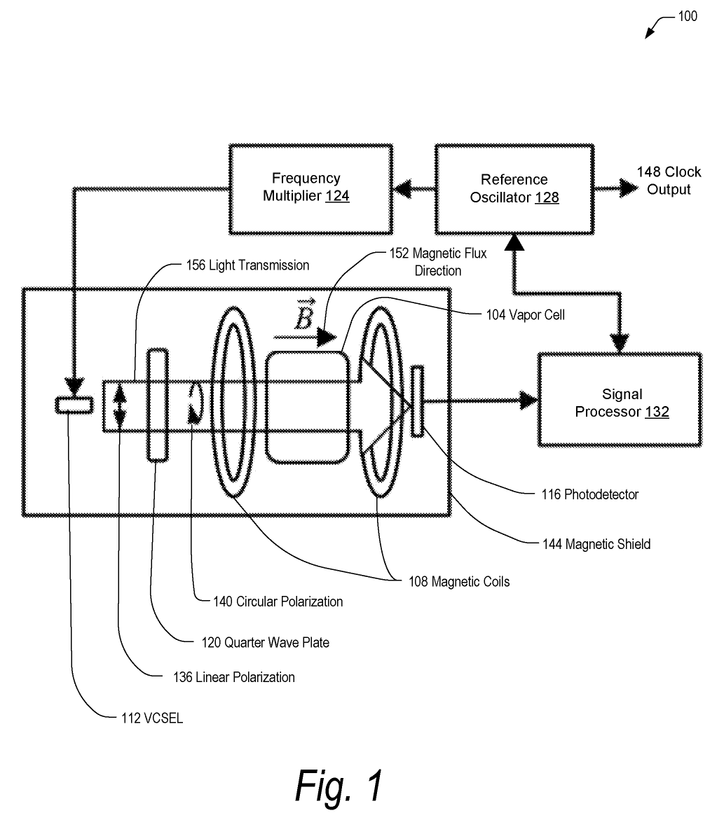

Referring to FIG. 1, a block diagram of a modular quantum sensor 100 in accordance with embodiments of the invention is shown. FIG. 1 illustrates the principal components of a quantum sensor 100 without regard to blade or other specific form of organization.

The quantum sensor 100 may include various components within a magnetic shield 144 and various components external to the magnetic shield 144. The magnetic shield 144 prevents stray external magnetic fields from influencing the magnetic coils 108 interaction with a vapor cell 104. The vapor cell 104 is an alkali metal vapor cell as understood by one of ordinary skill in the art. In one embodiment, the interior of the magnetic shield 144 may be a partial or complete vacuum or filled with an inert gas such as argon or nitrogen.

The external components include a frequency multiplier 124 that drives a VCSEL 112 to generate an optical beam at a frequency that corresponds to an atomic transition of the vapor cell 104. A reference oscillator 128 provides a stable frequency reference that drives the frequency multiplier 124. In an atomic clock application, the reference oscillator 128 is locked to the atomic resonance and provides a stable clock output 148. In other quantum sensor applications such as magnetometers or gyroscopes, a different form of output may be provided.

The reference oscillator 128 also provides a reference signal to a signal processor 132. In some embodiments, the reference oscillator 128 may be a voltage-controlled oscillator such as a VCTCXO or similar frequency-adjustable oscillator. The signal processor 132 receives an optical signal from a photodetector 116 within the magnetic shield 144 and generates an error signal by comparing the detected optical signal against the atomic transition frequency. In an atomic clock configuration, this error signal is fed back to the reference oscillator 128 to actively tune its output frequency into alignment with the atomic transition, thereby maintaining frequency lock and stabilizing the clock output 148. In magnetometer applications, the error signal corresponds to magnetic field strength, which is provided as the sensor output.

The VCSEL 112 provides a light transmission 156 path through the vapor cell 104. The VCSEL 112 and the photodetector 116 are endpoints of an optical pathway or alignment axis that is the heart of the quantum sensor device 100. Light from the VCSEL 112 is naturally linearly polarized 136 and is converted to circular polarization 140 by a quarter wave plate 120. Circular polarization is required for coherent population trapping (CPT) interactions with the alkali metal atoms in the vapor cell 104, where the circularly polarized light 140 simultaneously drives multiple atomic transitions to create a dark state used for quantum sensing.

The circularly polarized 140 light transmission passes through a pair of magnetic coils 108 and the vapor cell 104 itself. One magnetic coil 108 is positioned at the VCSEL 112 end of the vapor cell 104 and the other magnetic coil 108 is positioned at the photodetector 116 end of the vapor cell 104. The magnetic coils 108 produce a uniform magnetic flux along the alignment axis or magnetic flux direction 152. This axial magnetic field induces Zeeman splitting of the atomic energy levels, which is necessary for proper operation of the quantum sensor. The use of two coils 108 rather than a single coil 108 provides more uniform magnetic field distribution across the length of the vapor cell 104.

Other forms of quantum sensor different from an atomic clock (e.g., magnetometer) may have different components and arrangement to that shown in FIG. 1. FIG. 1 may thus be seen as an example of a complete quantum sensor device independent of modularity or packaging constraints.

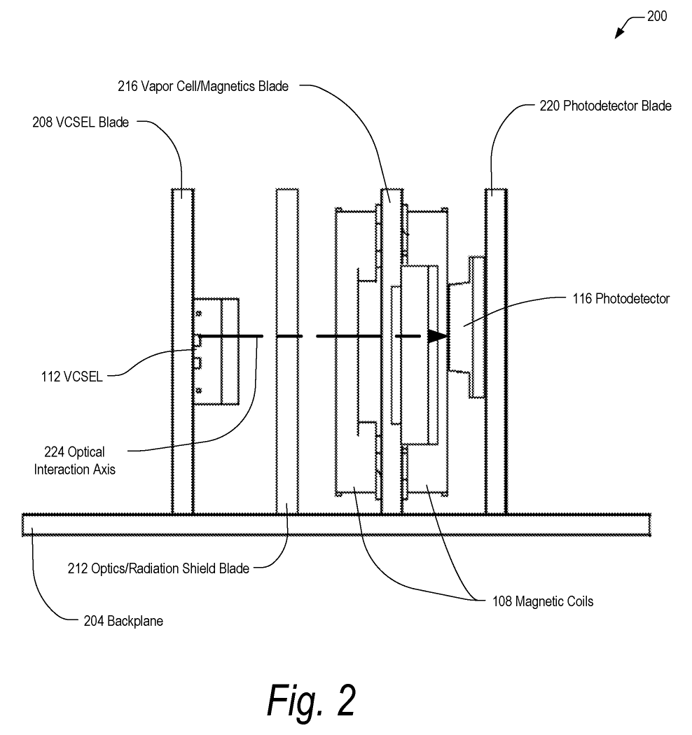

FIGS. 2-6 illustrate a modular quantum sensor assembly that includes a backplane 204 and a plurality of blades arranged along an optical interaction axis. The plurality of blades are unique modular assemblies that perform unique features and functions within a quantum vapor cell device.

Referring to FIG. 2, a side view of a modular quantum sensor 200 in accordance with embodiments of the invention is shown. The quantum sensor 200 includes a VCSEL blade 208, an optics/radiation shield blade 212, a vapor cell/magnetics blade 216, and a photodetector blade 220.

The optics/radiation shield blade 212 is positioned between the VCSEL blade 208 and the vapor cell/magnetics blade 216 and the vapor cell/magnetics blade 216 is positioned between the optics/radiation shield blade 212 and the photodetector blade 220. The optics/radiation shield blade 212 provides dual functionality critical to the thermal island architecture:
(1) Optical transparency along the interaction axis 224. The optics/radiation shield blade 212 is optically transparent at operational wavelengths corresponding to alkali metal atomic transitions. For rubidium-based vapor cells 104, the operational wavelength is approximately 795nm (Rb D1 line). For cesium-based vapor cells, the operational wavelength is approximately 895nm (Cs D1 line). The blade 212 permits transmission of light between active functional modules without substantial attenuation, beam distortion, or polarization degradation.
(2) Thermal radiation shielding. The optics/radiation shield blade 212 includes at least one thermally reflective surface oriented toward one or both adjacent active blades (e.g., the VCSEL blade 208 and/or the vapor cell/magnetics blade 216). The reflective surface reduces radiative heat transfer by reflecting infrared radiation while transmitting operational optical wavelengths. In certain embodiments, multilayer dielectric coatings may selectively reflect wavelengths above 2 micrometers (thermal infrared) while transmitting near-infrared wavelengths in the 750-900nm range used for quantum sensing.

The optics/radiation shield blade 212 may further include low thermal conductivity materials to reduce conduction heat transfer, reduce cross-sectional mounting interfaces to minimize conduction paths, and operate within vacuum gaps or reduced-pressure environments adjacent to the blade. Thermal isolation is characterized such that adjustment of a first operating temperature (e.g., VCSEL blade 208 operating at 70-85°C) produces less than a predetermined change in the second operating temperature (e.g., vapor cell/magnetics blade 216 operating at 85-95°C). In some embodiments, the predetermined threshold is less than 5°C. These structural features distinguish the optics/radiation shield blade 212 from simple mechanical spacers and provide functional radiative decoupling while preserving optical alignment in a miniaturized quantum sensor device.

In certain embodiments, the optics/radiation shield blade 212 may include multilayer dielectric anti-reflection coatings on optical surfaces to minimize reflection losses at the operational wavelengths (e.g., 795nm for rubidium or 895nm for cesium). The optics/radiation shield blade 212 may also incorporate additional optical conditioning elements such as meta surface features for beam shaping, microlens structures to maintain beam collimation, or quarter-wave plate functionality for polarization control.

The vapor cell/magnetics blade 216 includes a vapor cell 104 mounted to a substrate and magnetic elements (magnetic coils 108). In one embodiment, the vapor cell/magnetics blade 216 includes a magnetic shield surrounding the vapor cell 104 to attenuate external magnetic interference while preserving an internally generated magnetic bias field.

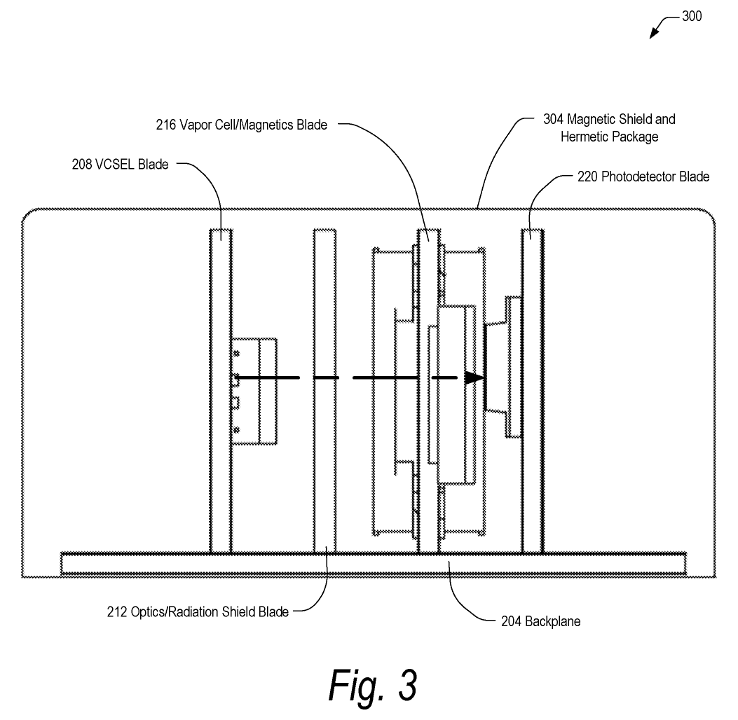

Referring to FIG. 3, a side view of a packaged modular quantum sensor 300 in accordance with embodiments of the invention is shown. The packaged quantum sensor 300 is similar to the modular quantum sensor 200 shown in FIG. 2. However, it also includes a magnetic shield and hermetic package 304 that encloses the blade assembly and backplane 204. The hermetic package 304 is atmospherically isolated from outside air and maintains a controlled internal environment. In some embodiments, the magnetic shield 144 forms part of the hermetic package 304.

In some embodiments, the hermetic package 304 contains a vacuum or reduced-pressure environment to minimize convective heat transfer between functional modules. Convective heat transfer becomes negligible at pressures below approximately 10⁻² Torr (0.01 Torr), providing effective thermal isolation between blades. In other embodiments, the hermetic package 304 may contain an inert gas such as argon, nitrogen, or krypton at reduced pressure to provide thermal isolation while potentially offering benefits such as reduced outgassing or improved long-term stability. The reduced-pressure or inert gas environment significantly reduces convective thermal coupling between blades 208, 212, 216, and 220, thereby enhancing the thermal isolation necessary for independent temperature control of each functional module.

The magnetic shield 144 portion of package 304 attenuates external magnetic field interference that could affect the magnetic coils 108 and vapor cell 104 operation. In some embodiments, the magnetic shield 144 may be constructed from mu-metal, permalloy, or other high-permeability magnetic shielding materials. The combined hermetic package 304 and magnetic shield 144 thus provides both thermal isolation enhancement (through reduced-pressure environment) and magnetic field isolation (through shielding materials) while maintaining the modular blade architecture along the optical interaction axis.

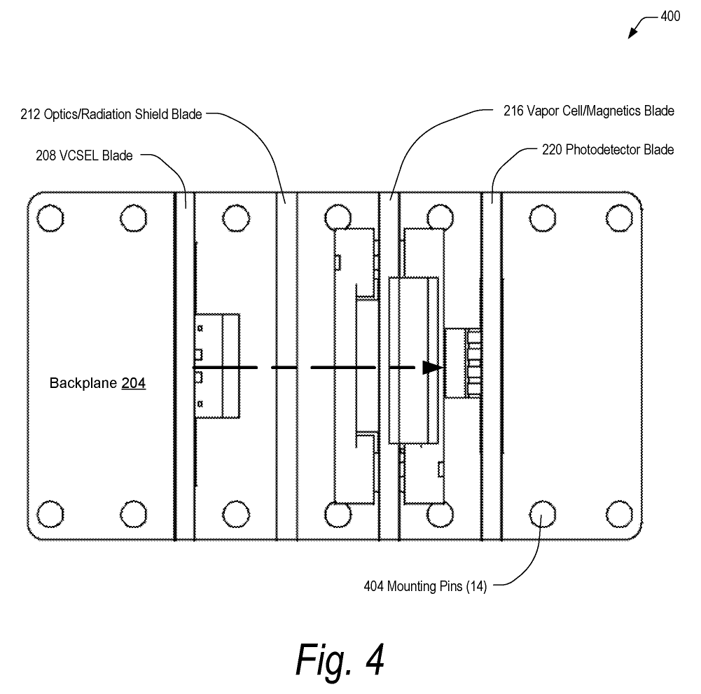

Referring to FIG. 4, a top view of a modular quantum sensor 400 in accordance with embodiments of the invention is shown. The top view illustrates the arrangement of the four functional modules on backplane 204: VCSEL blade 208, optics/radiation shield blade 212, vapor cell/magnetics blade 216, and photodetector blade 220. The blades are arranged in sequence along the optical interaction axis 224 with visible spacing between adjacent blades to provide thermal isolation.

A number of mounting pins 404 are provided to mount the backplane 204 to an underlying structure that supports the magnetic shield 144 and hermetic package 304. Although 14 such mounting pins 404 are shown, any number of mounting pins 404 may be present in various embodiments and alternatives, depending on package size, mechanical requirements, and electrical connection needs. The mounting pins 404 may provide both mechanical support and electrical connections to supply power and control signals to the temperature control systems and other components on each functional module.

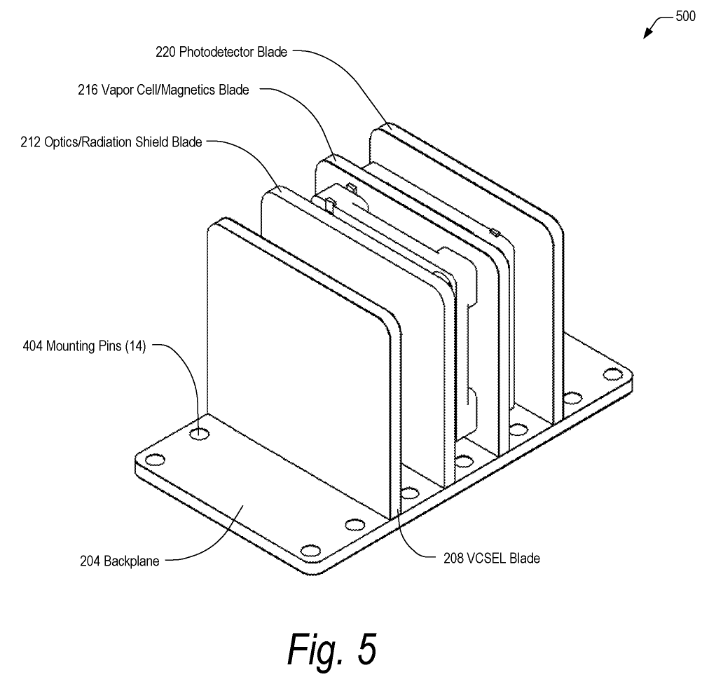

Referring to FIG. 5, an isometric view of a modular quantum sensor 500 in accordance with embodiments of the invention is shown. The isometric perspective illustrates the three-dimensional arrangement of the modular blade architecture, showing the height, width, and depth relationships between the backplane 204 and each of the functional modules: VCSEL blade 208, optics/radiation shield blade 212, vapor cell/magnetics blade 216, and photodetector blade 220.

FIG. 5 illustrates the approximate size and spatial relationships between the backplane 204 and each of the blades 208, 212, 216, and 220. The isometric view clearly shows the physical separation between adjacent blades, with gaps visible between the VCSEL blade 208 and optics/radiation shield blade 212, between the optics/radiation shield blade 212 and vapor cell/magnetics blade 216, and between the vapor cell/magnetics blade 216 and photodetector blade 220. These gaps provide thermal isolation between functional modules operating at different temperatures. The mounting pins 404 extending from the backplane 204 are also visible in this view, showing how the complete assembly may be mounted to a package or substrate.

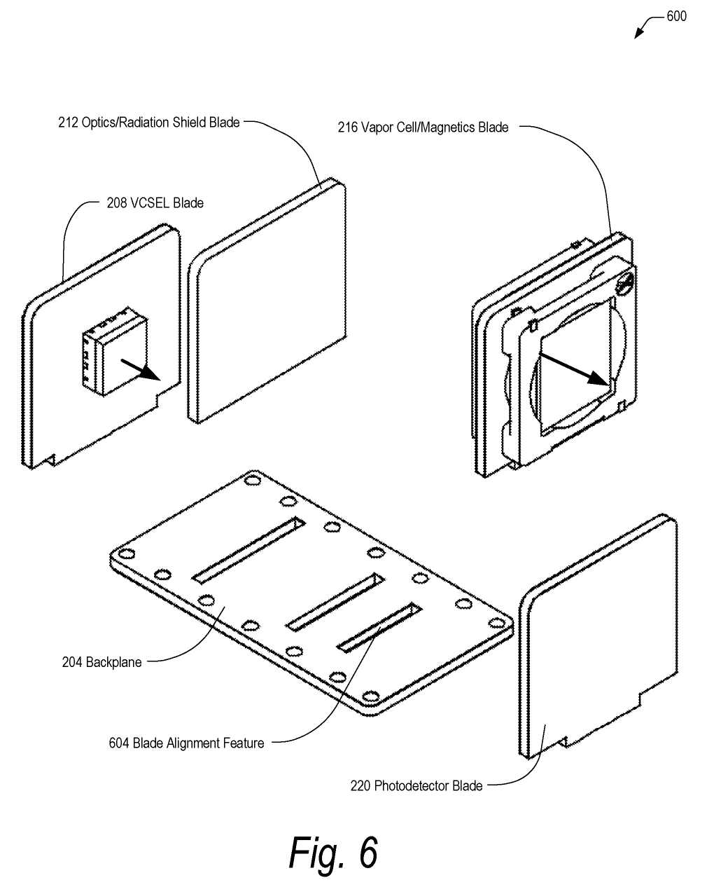

Referring to FIG. 6, an exploded view of a modular quantum sensor 600 in accordance with embodiments of the invention is shown. The exploded view illustrates how the individual functional modules—VCSEL blade 208, optics/radiation shield blade 212, vapor cell/magnetics blade 216, and photodetector blade 220—are assembled onto backplane 204 to form the complete quantum sensor device.

Each blade is independently temperature controlled and mechanically registered using alignment features 604 of backplane 204. The alignment features 604 may take various forms including, but not limited to, slots, grooves, pins, posts, clips, mounting pads, registration marks, mating slots and blade insertion tabs formed in the backplane 204, or other mechanical structures that establish the position and orientation of each blade relative to the backplane 204 and adjacent blades. The alignment features 604 facilitate positioning of the blades along the optical interaction axis 224 while maintaining thermal isolation gaps between adjacent modules.

In some embodiments, each functional module may be tested independently at its respective target operating temperature prior to assembly into the modular quantum sensor device, as enabled by the physically separable blade architecture shown in the exploded view 600. Modules that meet performance specifications are selected for assembly, while modules that fail specifications can be rejected before final assembly, thereby improving manufacturing yield and speed of assembly.

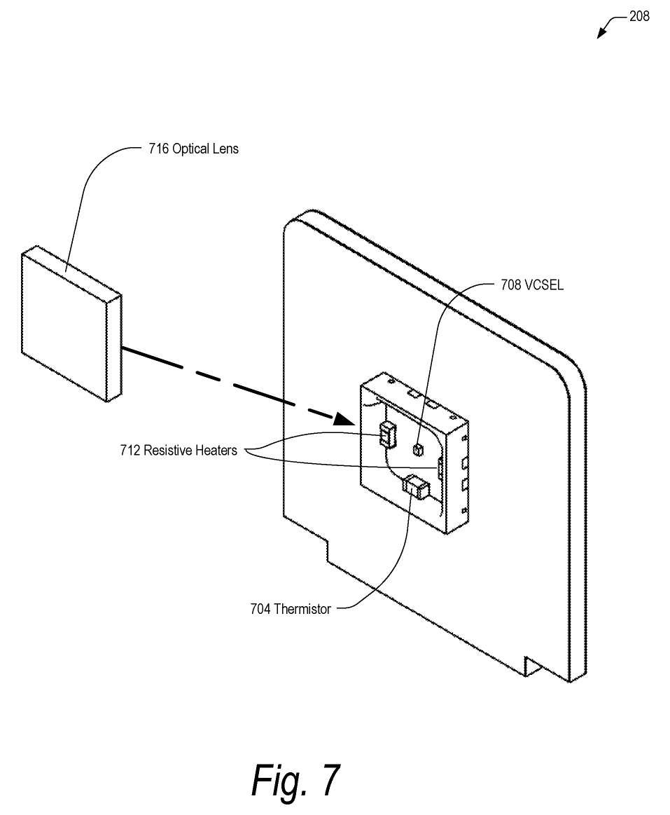

Referring to FIG. 7, an isometric view of a VCSEL blade 208 in accordance with embodiments of the invention is shown. The VCSEL blade 208 is a complete functional module with integrated temperature control, representing one of the thermal islands in the modular quantum sensor architecture.

The VCSEL blade 208 includes a VCSEL device 708, resistive heaters 712, a thermistor 704, and an optical lens 716 mounted to a substrate, such as a silicon substrate, an FR-4 printed circuit board, or a ceramic or other thermally stable material selected based on thermal management requirements, cost, and manufacturability. In some embodiments, the substrate may include thermal isolation features such as reduced cross-sectional support areas or low thermal conductivity materials to minimize heat loss to the backplane 204.

The resistive heaters 712 are electrically coupled to a temperature control circuit (not shown) that maintains the VCSEL 708 at a controlled operating temperature.

In other embodiments, heating may be provided by transistor-based heaters, resistive traces integrated into the substrate, or other heating elements positioned to control the VCSEL temperature. The thermistor 704 provides temperature feedback to the control circuit, enabling closed-loop temperature regulation with stability better than 50mK in some embodiments. Precise temperature control stabilizes the VCSEL wavelength output for the light transmission 156, as VCSEL emission wavelength is temperature dependent.

Temperature adjustment enables tuning of the emitted wavelength to match an atomic transition frequency within the vapor cell 104. This post-selection tuning capability is a key advantage of the thermal island architecture. For example, a VCSEL 708 that emits at 796nm at a nominal temperature of 70°C can be temperature-adjusted to emit at the target wavelength of 795nm (rubidium D1 line) by adjusting the operating temperature to approximately 85°C. This eliminates the need for wavelength-binned VCSEL 708 inventory and improves manufacturing yield by allowing use of components whose wavelength can be tuned into specification through temperature adjustment rather than requiring pre-selection of components that meet wavelength specifications at a fixed temperature.

In the embodiment illustrated, an optional optical lens 716 may collimate or condition the output beam from VCSEL 708. In other embodiments, optical conditioning may be provided by separate optical modules, or the VCSEL output may be used directly without additional optics.

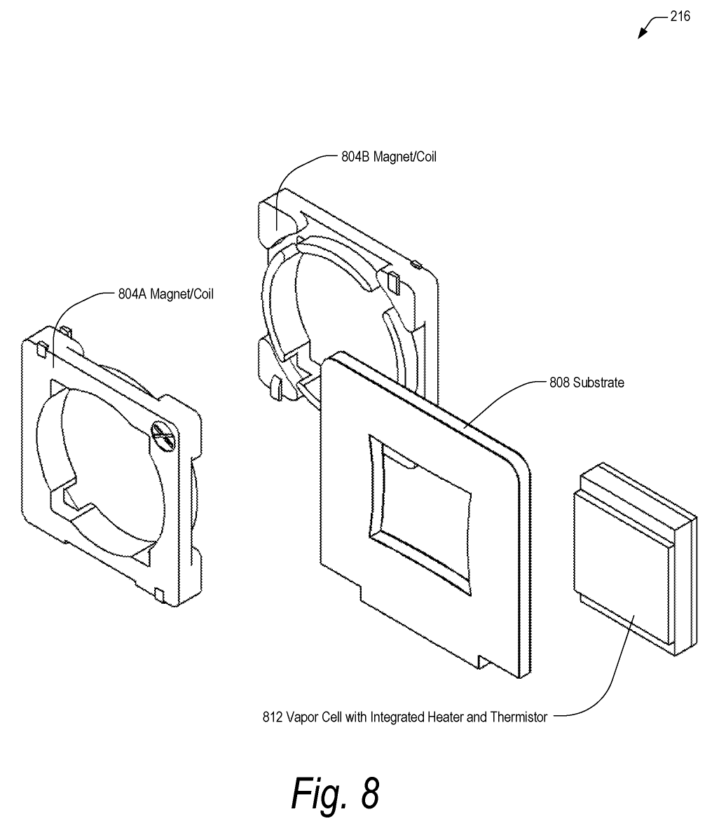

Referring to FIG. 8, an exploded isometric view of a vapor cell/magnetics blade 216 in accordance with embodiments of the invention is shown. The vapor cell/magnetics blade 216 is a complete functional module with integrated temperature control and magnetic field generation, representing a thermal island that typically operates at a higher temperature than the VCSEL blade 208.

The vapor cell/magnetics blade 216 includes a vapor cell 812 mounted to a substrate 808 and magnetic elements 804A, 804B positioned on either side of the vapor cell 812. The vapor cell 812 includes alkali metal vapor (such as rubidium or cesium) and includes integrated heating and temperature sensing for maintaining an operating temperature optimized for vapor density. In some embodiments, the vapor cell 812 operates in a temperature range between 80°C and 100°C, depending on the alkali metal species and desired vapor pressure. This operating temperature is independently controlled and typically different from the VCSEL 708 operating temperature (typically 70-85°C), illustrating the advantage of the thermal island architecture where each functional module maintains its optimal operating temperature.

The vapor cell 812 includes integrated heating and temperature sensing elements. In the embodiment shown, the heater and thermistor are integrated within the vapor cell assembly 812 itself. In other embodiments, heating and temperature sensing may be provided by discrete components positioned on the substrate 808, on the vapor cell mounting structure, or at other locations thermally coupled to the vapor cell. The heating element may be a resistive heater, a transistor-based heater, or other heating structure capable of maintaining the vapor cell at the target operating temperature. The temperature sensor may be a thermistor, thermocouple, resistance temperature detector (RTD), or other temperature sensing element that provides feedback for closed-loop temperature control. Regardless of the specific heating and sensing implementation, the vapor cell/magnetics blade 216 maintains independent temperature control isolated from adjacent functional modules through the thermal isolation architecture.

The magnetic elements 804A, 804B generate a magnetic field along the optical interaction axis through the vapor cell 812. This axial magnetic field induces Zeeman splitting of the atomic energy levels, which is necessary for proper quantum sensor operation. In some embodiments, the magnetic elements may be permanent magnets, electromagnets, or magnetic coils that produce a uniform bias field across the vapor cell length.

Various substrate 808 materials may be used depending on optical, thermal, and mechanical requirements, including borosilicate glass, fused silica, sapphire, silicon, or silicon-on-insulator. The substrate material 808 selection may consider factors such as coefficient of thermal expansion matching with the vapor cell, optical transmission requirements, thermal conductivity, and cost.

The vapor cell 812 includes optical windows bonded at each end to seal the alkali metal vapor within the vapor cell 812. The optical window may be bonded through various techniques including anodic bonding, fusion bonding, frit glass bonding, eutectic bonding, or thermocompression bonding, depending on the substrate 808 and window materials. The exploded view in FIG. 8 illustrates how the vapor cell 812, magnetic elements 804A and 804B, and substrate 808 are assembled to form the complete vapor cell/magnetics blade 216.

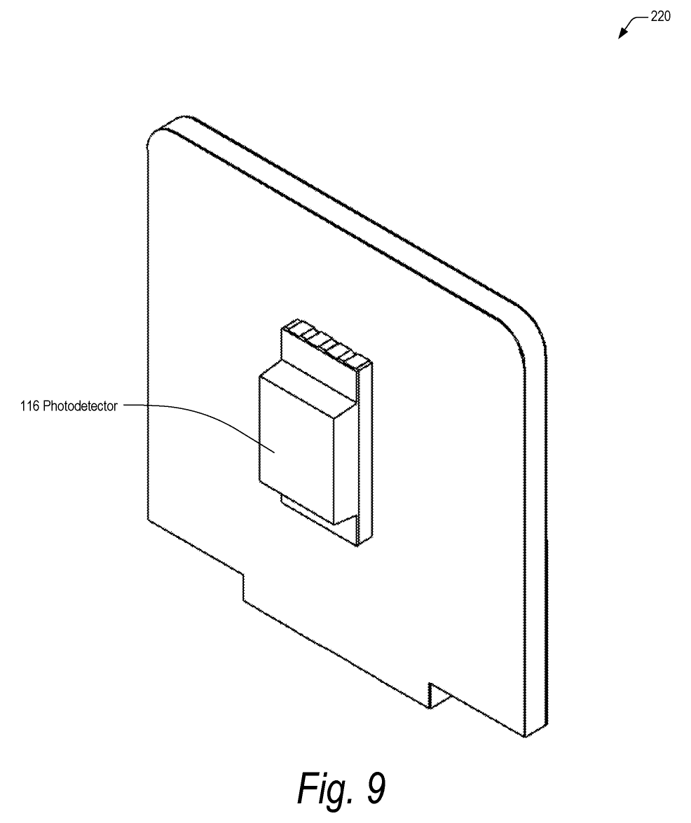

Referring to FIG. 9, an isometric view of a photodetector blade 220 in accordance with embodiments of the invention is shown. The photodetector blade 220 is a functional module that detects light transmission through the vapor cell 104 and converts the optical signal to an electrical signal for processing by the signal processor 132.

The photodetector blade 220 includes a photodetector 116 mounted to a substrate, such as a silicon substrate or an FR-4 printed circuit board. The photodetector 116 may be a photodiode, phototransistor, or other light-sensitive detector element with appropriate spectral response for the operational wavelength (such as 795nm for rubidium or 895nm for cesium).

In some embodiments, the photodetector blade 220 may include temperature sensing elements (such as a thermistor or RTD) to monitor photodetector temperature, enabling compensation for temperature-dependent characteristics such as responsivity drift or dark current variations.

Unlike the VCSEL blade 208 and vapor cell/magnetics blade 216, which require active temperature control to maintain specific operating temperatures, the photodetector blade 220 typically operates at ambient temperature or at a temperature determined by thermal coupling to adjacent modules and the hermetic package 304 environment. The modular architecture enables the photodetector blade 220 to be independently tested for responsivity, dark current, and spectral response prior to assembly into the complete quantum sensor device.

The photodetector blade 220 may include electrical connections for delivering the photodetector output signal to the signal processor 132 via connections through the backplane 204. In some embodiments, the photodetector blade 220 may include signal conditioning circuitry such as transimpedance amplifiers, filters, or analog-to-digital converters, or such signal processing may be located on the backplane 204 or in external circuitry elsewhere.

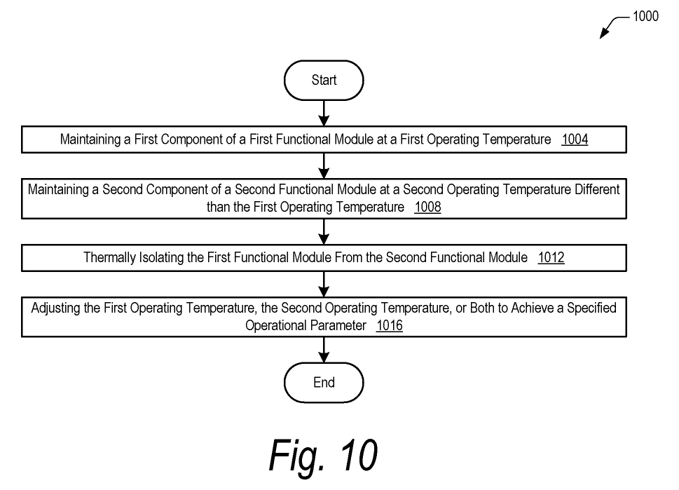

Referring to FIG. 10, a flowchart of a thermal management process for a modular quantum vapor cell 1000 in accordance with embodiments of the invention is shown. The flowchart demonstrates how independent temperature control of functional modules enables post-selection tuning and operational optimization. Flow begins at block 1004.

At block 1004, the process includes maintaining a first component of a first functional module at a first operating temperature. For example, a temperature control system regulates power to resistive heaters 712 on the VCSEL blade 208. Feedback from thermistor 704 stabilizes the VCSEL junction temperature to maintain a target emission wavelength. In some embodiments, this step may occur during independent testing of the VCSEL blade 208 prior to assembly, enabling verification that the VCSEL achieves the target wavelength at the controlled temperature. Flow proceeds to block 1008.

At block 1008, the process includes maintaining a second component of a second functional module at a second operating temperature different than the first operating temperature. For example, the vapor cell heater maintains the vapor cell 812 at a temperature optimized for alkali vapor density, typically between 80°C and 100°C. The integrated thermistor provides closed-loop control with temperature stability better than 50mK in some embodiments. This temperature is independently controlled and typically different from the VCSEL operating temperature (70-85°C). Like the first functional module, the vapor cell/magnetics blade 216 may be independently tested at its target operating temperature prior to assembly. Flow proceeds to block 1012.

At block 1012, the process includes thermally isolating the first functional module from the second functional module. Thermal isolation may be achieved through multiple mechanisms including the optics/radiation shield blade 212 with thermally reflective surfaces, vacuum or reduced-pressure spacing (below 10⁻² Torr for negligible convective transfer), and reduced-conduction support structures. The thermal isolation limits heat transfer such that adjustment of the first operating temperature causes a change in the second operating temperature of less than a predetermined threshold (such as less than 5°C). This thermal isolation enables independent temperature control and is a key enabler of post-selection tuning. Flow proceeds to block 1016.

At block 1016, the process includes adjusting the first operating temperature, the second operating temperature, or both, to achieve a specified operational parameter. This post-selection tuning capability eliminates the need for component binning and improves manufacturing yield. For example, if a VCSEL 708 emits at 796nm at 70°C (slightly off target), the temperature can be adjusted to approximately 85°C to shift the wavelength to the target 795nm for rubidium D1 line operation. Similarly, the vapor cell 104 temperature may be adjusted to optimize vapor density and maximize signal amplitude. In atomic clock applications, temperature adjustments may optimize clock frequency stability. In magnetometer applications, temperature adjustments may optimize magnetic field sensitivity. Flow ends at block 1016.

Modular quantum sensors incorporating the thermal island architecture as described herein may be used for many applications, including chip-scale atomic clocks, atomic magnetometers, quantum gyroscopes, and other types of quantum sensors. The independent temperature control enabled by thermal isolation between functional modules provides manufacturing and operational advantages across these diverse applications.

For chip-scale atomic clocks, the modular architecture enables independent optimization of light source wavelength and vapor cell temperature, improving frequency stability and reducing manufacturing costs. Chip-scale atomic clocks incorporating thermal island architecture may provide stable frequency references for GPS-denied navigation, telecommunications, distributed sensor networks, and precision instrumentation.

For atomic magnetometers, independent temperature control of the light source and vapor cell enables optimization of magnetic field sensitivity while maintaining stable operation across varying ambient temperatures. Atomic magnetometers incorporating thermal island architecture may measure magnetic fields with high sensitivity for geophysical exploration, biomedical imaging, defense applications, and fundamental physics research.

For quantum gyroscopes, the modular thermal island architecture enables independent optimization of each functional module for rotation sensing performance. Quantum gyroscopes incorporating thermal island architecture may detect rotation rates for inertial navigation systems in GPS-denied environments, autonomous vehicles, and aerospace applications.

The modular architecture additionally enables configuration flexibility where the same basic blade types (light source 208, optical conditioning 212, vapor cell 216, and/or detection 220) can be adapted for different alkali metal species, different optical wavelengths, and different sensing modalities while maintaining the core manufacturing advantages of independent testing, post-selection tuning, and improved yield.

Various embodiments of the invention have been described in fulfillment of the various objectives of the invention. It should be recognized that these embodiments are merely illustrative of the principles of the present invention. Numerous modifications and adaptations thereof will be readily apparent to those skilled in the art without departing from the spirit and scope of the present invention as defined in the following claims.

What is claimed is:

1. A quantum sensor device, comprising:
a first functional module comprising a first component and a first temperature control system configured to maintain the first component at a first operating temperature;
a second functional module comprising a second component and a second temperature control system configured to maintain the second component at a second operating temperature different from the first operating temperature; and
a thermal isolation structure disposed between the first functional module and the second functional module, the thermal isolation structure comprising one or more of a vacuum gap, a radiation shield, or a reduced conduction support structure,
wherein the thermal isolation structure limits heat transfer between the first and second functional modules such that adjustment of the first operating temperature causes a change in the second operating temperature of less than a predetermined threshold.

2. The quantum sensor device of claim 1, wherein the first and second functional modules include one or more of:
a light generation module;
an interaction module comprising an atomic vapor cell; and
a light detection module.

3. The quantum sensor device of claim 2, wherein the light generation module is configured such that an output wavelength is tunable through temperature adjustment to match an atomic transition frequency of the atomic vapor cell.

4. The quantum sensor device of claim 2, wherein the atomic vapor cell comprises:
a sealed atomic vapor chamber; and
an integrated heating element configured to maintain the vapor chamber at a temperature different from that of the light generation module.

5. The quantum sensor device of claim 1, wherein each functional module includes one or more thermal management components configured to regulate an operating temperature of that module independently of the other modules.

6. The quantum sensor device of claim 1, wherein the thermal isolation structure is selected from a vacuum gap, a radiation shield, and a reduced-conduction support structure.

7. The quantum sensor device of claim 6, wherein the thermal isolation structure is configured to maintain the functional modules in one or more of a reduced-pressure environment or inert gas environment to reduce convective thermal transfer between functional modules.

8. The quantum sensor device of claim 6, wherein the radiation shield comprises a thermally reflective surface positioned to reduce radiative thermal transfer between adjacent functional modules operating at different temperatures.

9. The quantum sensor device of claim 1, wherein the first functional module is tested independently of the second functional module prior to assembling into the quantum sensor device.

10. The quantum sensor device of claim 9, wherein testing comprises evaluating performance while operating each functional module at a target operating temperature that corresponds to the functional module being tested.

11. A quantum sensing system comprising:
a modular quantum device assembly comprising a plurality of functional modules arranged along an interaction axis, the functional modules comprising:
a light generation module;
an interaction module comprising an atomic vapor cell; and
a light detection module,
the modules being mechanically aligned by predefined alignment features that establish optical coupling along the interaction axis upon assembly, and
each functional module including independent temperature control and configured to maintain an operating temperature independent of operating temperatures of other functional modules.

12. The quantum sensing system of claim 11, wherein the light generation module is configured such that an output wavelength is tunable through temperature adjustment to match an atomic transition frequency of the atomic vapor cell.

13. The quantum sensing system of claim 11, wherein the atomic vapor cell comprises:
a sealed atomic vapor chamber; and
an integrated heating element configured to maintain the vapor chamber at a temperature different from that of the light generation module.

14. The quantum sensing system of claim 11, wherein each functional module includes one or more thermal management components configured to regulate an operating temperature of that module independently of the other modules.

15. The quantum sensing system of claim 11, wherein the functional modules are separated by one or more thermal isolation features selected from a vacuum gap, a radiation shield, and a reduced-conduction support structure.

16. The quantum sensing system of claim 15, wherein the one or more thermal isolation features are configured to maintain the functional modules in one or more of a reduced-pressure environment or inert gas environment to reduce convective thermal transfer between functional modules.

17. The quantum sensor system of claim 11, wherein the plurality of functional modules are tested independently prior to assembling into the quantum sensor device.

18. The quantum sensor system of claim 17, wherein testing comprises evaluating performance while operating each of the plurality of functional modules at a target operating temperature that corresponds to the functional module being tested.

19. A method of operating a quantum sensor device, comprising:
maintaining by a first temperature control system, a first component of a first functional module at a first operating temperature;
maintaining by a second temperature control system, a second component of a second functional module at a second operating temperature different from the first operating temperature;
thermally isolating the first functional module from the second functional module, by one or more of a vacuum gap, a radiation shield, or a reduced conduction support structure, such that adjustment of the first operating temperature by the first temperature control system does not cause a change in the second operating temperature beyond a predetermined threshold; and
adjusting the first operating temperature, the second operating temperature, or both, to achieve a specified operational parameter of the quantum sensor device.

20. The method of claim 19, wherein the first and second functional modules include one or more of:
a light generation module;
an interaction module comprising an atomic vapor cell; and
a light detection module.

21. The method of claim 20, wherein the light generation module is configured such that an output wavelength is tunable through temperature adjustment to match an atomic transition frequency of the atomic vapor cell.

22. The method of claim 19, wherein each of the first and second functional modules include one or more thermal management components configured to regulate an operating temperature of one of the first and second functional modules independently of the other of the first and second functional modules.

23. The method of claim 19, wherein each of the plurality of functional modules are separated by one or more thermal isolation features selected from a vacuum gap, a radiation shield, and a reduced-conduction support structure.

24. The method of claim 23, further comprising:
maintaining, by the one or more thermal isolation features, the plurality of functional modules in one or more of a reduced-pressure environment or inert gas environment to reduce convective thermal transfer between functional modules.

25. The method of claim 19, further comprising:
independently testing the plurality of functional modules prior to assembling into the quantum sensor device.

26. The method of claim 25, wherein independent testing comprises evaluating performance while operating each functional module at a target operating temperature that corresponds to the functional module being tested.
